(19) United States
(12) Patent Application Publication
(10) Pub. No.: US 2007/0215878 A1
(43) Pub. Date: Sep. 20, 2007

(54) Light emitting device

(76) Inventors: Dong-Sing Wuu, Taichung City (TW); Ray-Hua Horng, Taichung City (TW)

Correspondence Address: DAVIDSON BERQUIST JACKSON & GOWDEY LLP, 4300 WILSON BLVD., 7TH FLOOR, ARLINGTON, VA, 22203, US

(21) Appl. No.: 11/377,835

(22) Filed: Mar. 17, 2006

(51) Int. Cl. H01L 29/04

(52) U.S. Cl. 257/72

(57) ABSTRACT

A light emitting device includes: a substrate; a current diffusion layer; and a light emitting structure sandwiched between the substrate and the current diffusion layer, and including a plurality of light emitting protrusions extending between the substrate and the current diffusion layer, a plurality of interconnected spaces disposed among and separating the light emitting protrusions from each other, and a dielectric material filling the spaces. Each of the light emitting protrusions includes first and second cladding layers and a light-emitting active layer sandwiched between the first and second cladding layers.

### BACKGROUND OF THE INVENTION

1. Field of the Invention

This invention relates to a light emitting device, more particularly to a light emitting device including a plurality of light emitting protrusions sandwiched between a substrate and a current diffusion layer.

2. Description of the Related Art FIG. 1 illustrates a conventional light emitting device that includes a sapphire substrate 10, a GaN buffer layer 111 formed on the sapphire substrate 10, and a plurality of light emitting protrusions 1′ that protrude from the GaN buffer layer 111. Each of the light emitting protrusions 1′ includes a Si-doped GaN layer 112, an active layer 113, and a Mg-doped GaN layer 114. A dielectric layer 12 of silicon dioxide covers a surrounding surface of each of the light emitting protrusions 1′. A spreading film 13 covers the dielectric layer 12 and top surfaces of the light emitting protrusions 1′. A first electrode 14 is formed on an exposed region of the Si-doped GaN layer 112. A second electrode 15 is formed on the spreading film 13 at a selected one of the protrusions 1′. The light emitting device thus formed can enhance the external quantum effect thereof. However, the thermal stress of the conventional light emitting device is relatively high due to a large contact area between the sapphire substrate 10 and the GaN buffer layer 111, thereby resulting in an adverse effect on the reliability of the light emitting device. In addition, the current flow in the conventional light emitting device is conducted in a horizontal feedthrough manner. As a consequence, once the first electrode 14 is damaged, all of the light emitting protrusions 1′ cannot be activated.

### SUMMARY OF THE INVENTION

The object of the present invention is to provide a light emitting device that is capable of overcoming at least one of the aforesaid drawbacks associated with the prior art.

According to this invention, a light emitting device comprises: a substrate; a current diffusion layer; and a light emitting structure sandwiched between the substrate and the current diffusion layer, and including a plurality of light emitting protrusions extending between the substrate and the current diffusion layer, a plurality of interconnected spaces disposed among and separating the light emitting protrusions from each other, and a dielectric material filling the spaces. Each of the light emitting protrusions includes first and second cladding layers and a light-emitting active layer sandwiched between the first and second cladding layers.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a fragmentary schematic view of a conventional light emitting device;

FIG. 2 is a fragmentary schematic view of the first preferred embodiment of a light emitting device according to this invention;

FIG. 3 is a fragmentary perspective view of a wafer including a plurality of the light emitting devices of the first preferred embodiment;

FIGS. 4A to 4F and 5A to 5D are schematic views to illustrate consecutive steps of a method for making the first preferred embodiment;

FIG. 6 is a fragmentary schematic view of the second preferred embodiment of the light emitting device according to this invention;

FIG. 7 is a graph illustrating the relationship between the electroluminescence spectrum and the testing time for the first preferred embodiment from an aging test; and

FIG. 8 is a graph illustrating the relationship between the positive biased voltage and the testing time for the first preferred embodiment from another aging test.

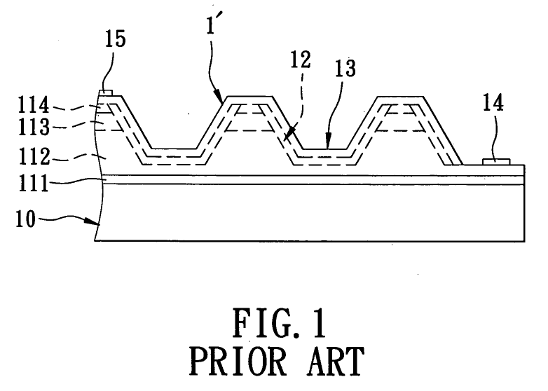

### DETAILED DESCRIPTION OF THE PREFERRED EMBODIMENTS

For the sake of brevity, like elements are denoted by the same reference numerals throughout the disclosure.

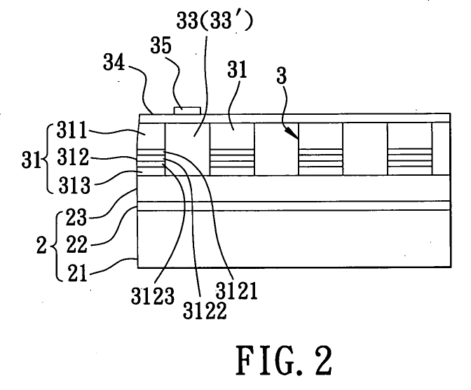

FIG. 2 illustrates the first preferred embodiment of a light emitting device according to this invention.

The light emitting device includes: a substrate 2; a current diffusion layer 34; and a light emitting structure 3 sandwiched between the substrate 2 and the current diffusion layer 34, and including a plurality of light emitting protrusions 31 extending between the substrate 2 and the current diffusion layer 34, a plurality of interconnected spaces 33, disposed among and separating the light emitting protrusions 31 from each other, and a dielectric material 33 filling the spaces 33′. Each of the light emitting protrusions 31 includes first and second cladding layers 311, 313 and a light-emitting active layer 312 sandwiched between the first and second cladding layers 311, 313.

In this embodiment, each of the light emitting protrusions 31 is columnar in shape.

substrate 2 includes a layered structure that has a bonding layer 22 of a metal material selected from the group consisting of Au, Al, Ti, Sn, Pt, In, Ag, Be, and gold-containing alloy. Preferably, the layered structure further includes a base layer 21 of a metal material selected from the group consisting of Cu, copper-containing alloy, Ni, nickel-containing alloy, tungsten-molybdenum alloy, and dopant-doped silicon, and a reflective layer 23 of a metal material selected from the group consisting of Pt, Ag, Ti, Au, Al, In, and Pd. The bonding layer 22 is sandwiched between the base layer 21 and the reflective layer 23. Preferably, the bonding layer 22 is a three-layer structure of aluminum, titanium, and gold.

this embodiment, the base layer 21 is made from copper, and the reflective layer is made from Pt.

Each of the light emitting protrusions 31 comprises a GaN type compound semiconductor material. The first and second cladding layers 311, 313 of each of the light emitting protrusions 31 are made from n-type GaN and p-type GaN compound materials, respectively. The first cladding layers 311 of the light emitting protrusions 31 are bonded to the current diffusion layer 34. The second cladding layers 313 of the light emitting protrusions 31 are bonded to the reflective layer 23 of the substrate 2. The active layer 312 of each of the light emitting protrusions 31 includes a n-type AlGaN film 3121 bonded to the first cladding layer 311, a p-type AlGaN film 3123 bonded to the second cladding layer 313, and a multi-layer structure 3122 of InGaN/GaN sandwiched between the n-type AlGaN film 3121 and the p-type AlGaN film 3123.

The dielectric material 33 is preferably made from silicon dioxide. The current diffusion layer 34 is preferably made from indium-tin oxide (ITO).

In this embodiment, the base layer 21 serves as a first electrode, while a second electrode 35 is formed on the current diffusion layer 34.

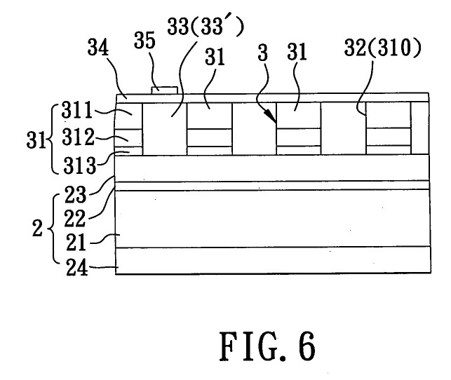

FIG. 6 illustrates the second preferred embodiment of the light emitting device according to this invention. The light emitting device of this embodiment differs from the previous embodiment in that the base layer 21 is made from a dopant-doped silicon, such as boron-doped silicon, and that a contact layer 24 of silver is formed on the base layer 21 to serve as the first electrode.

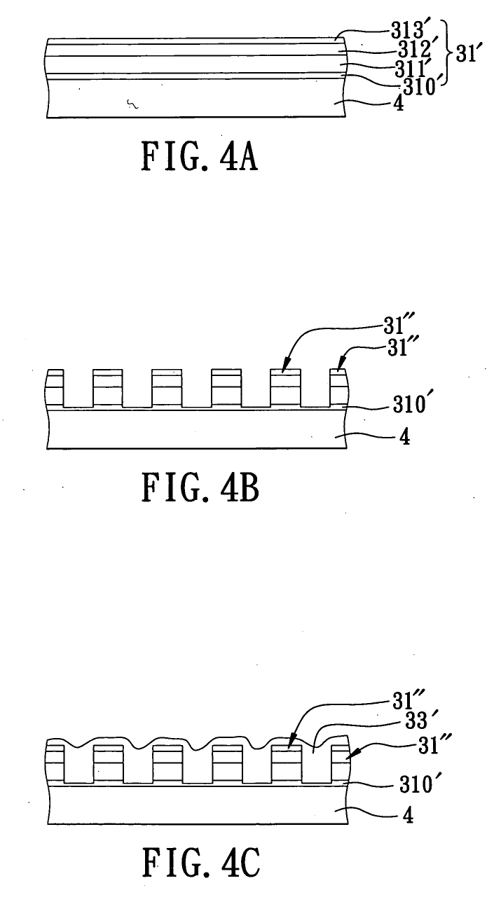

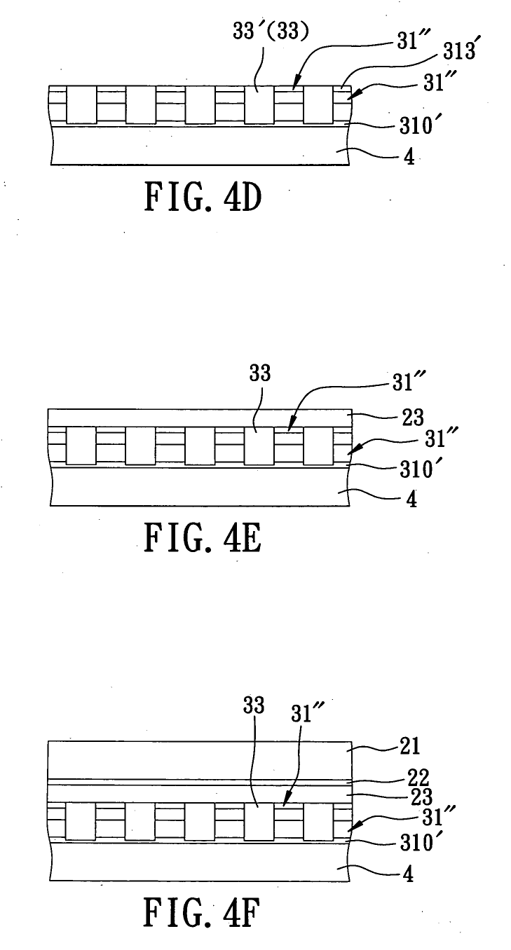

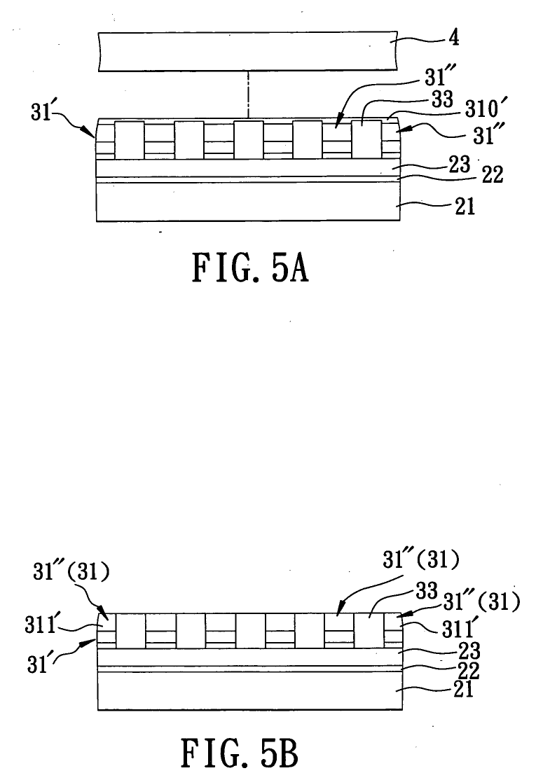

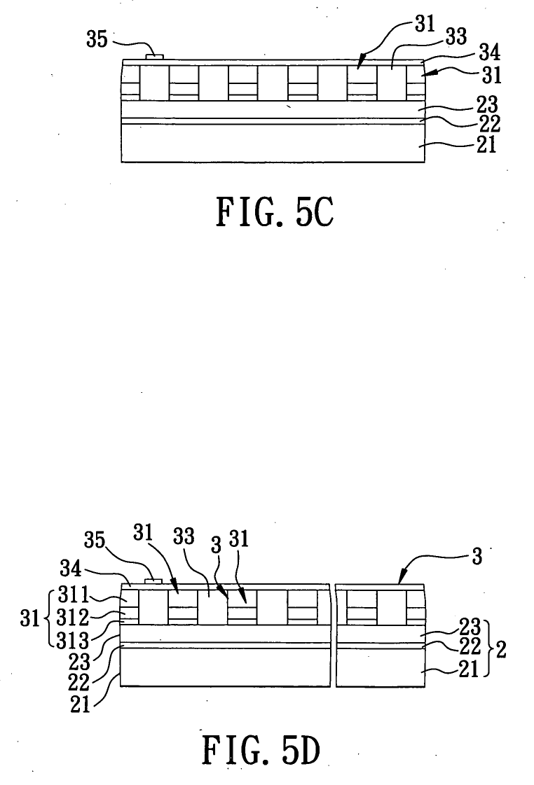

FIGS. 4A to 4F and 5A to 5D illustrate the consecutive steps of a method for making the light emitting device of the first preferred embodiment.

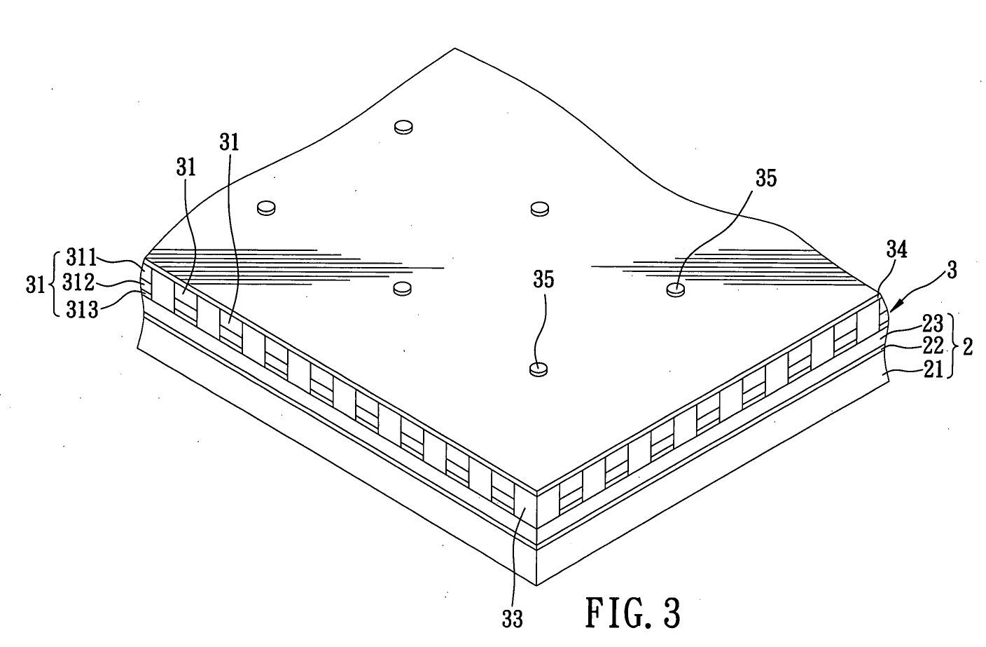

The method includes the steps of: forming an epitaxial layer 31′ on a sapphire substrate 4 (see FIG. 4A) by successively forming a GaN buffer layer 310′, a n-type GaN cladding layer 311′, an active layer 312′, and a p-type GaN cladding layer 313′ on the sapphire substrate 4; dry etching the epitaxial layer 31′ (see FIG. 4B) so as to form an array of protrusions 31″, each of which extends from the p-type GaN cladding layer 313′ to the GaN buffer layer 310′; forming a silicon dioxide layer 33′ (see FIG. 4C) using high density plasma chemical vapor deposition techniques (HDPCVD) such that the silicon dioxide layer 33′ fills spaces among the protrusions 31″ and covers the protrusions 31″; polishing the silicon dioxide layer 33′ to an extent such that the p-type GaN cladding layer 313′ of each of the protrusions 31″ is exposed (see FIG. 4D), the polished silicon dioxide layer 33′ corresponding to the dielectric material 33 of the first preferred embodiment; forming the reflective layer 23 of Pt on the dielectric material 33 (see FIG. 4E) and the exposed protrusions 31″; attaching the base layer 21 together with the bonding layer 22 of copper to the reflective layer 23 (see FIG. 4F) using wafer bonding techniques; irradiating the GaN buffer layer 310′ using a laser beam so as to decompose the GaN buffer layer 310′ and so as to remove the sapphire substrate 4 from the epitaxial layer 31′ (see FIG. 5A); removing the GaN buffer layer 310′ from the epitaxial layer 31′ (see Fig. SB) using polishing techniques so as to define the light emitting protrusions 31; forming the current diffusion layer 34 of indium-tin oxide (ITO) on the dielectric material 33 and the light emitting protrusions 31 (see FIG. 5C); forming the first electrodes 35 (see FIGS. 3 and 5C) on the current diffusion layer 34; and dicing the assembly obtained from the previous step so as to form a plurality of light emitting devices (see FIG. 5D).

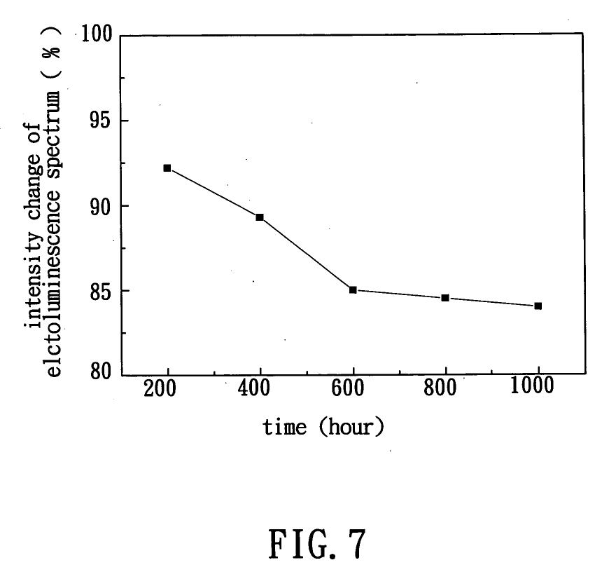

FIG. 7 illustrates the results of the intensity change of electroluminescence spectrum and the testing time for the first preferred embodiment from an aging test under an injecting current of 20 mA. Ther esults show that the intensity change of electroluminescence spectrum of the first preferred embodiment was less than 20% after 1000 testing hours.

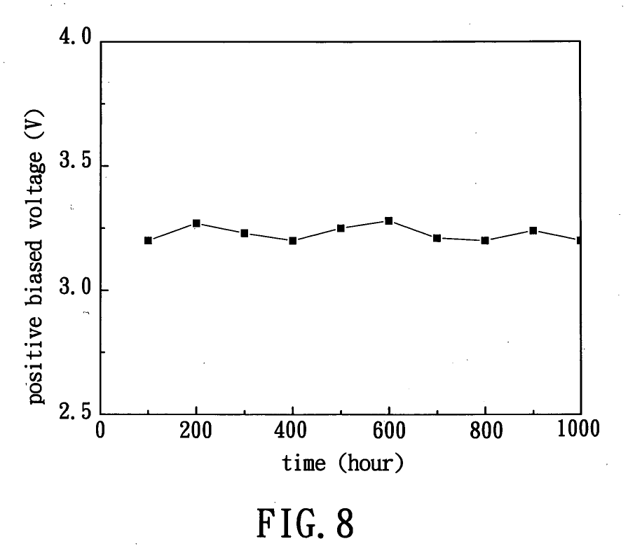

FIG. 8 illustrates the results of the relationship between the positive biased voltage and the testing time for the first preferred embodiment from another aging test under an injecting current of 20 mA. The results show that the positive biased voltage maintains at a range of from 3.2-3.3 volts during a period of 1000 testing hours.

The aging tests show that the light emitting device thus formed according to the method of this invention exhibits a high working reliability. Hence, the reduction in the contact area between the light emitting structure 31 and the substrate 2 can considerably reduce the thermal stress during activation of the light emitting device as encountered in the prior art, thereby enhancing the working reliability of the light emitting device.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

What is claimed is:

1. A light emitting device comprising:
a substrate;
a current diffusion layer; and
a light emitting structure sandwiched between said substrate and said current diffusion layer and including a plurality of light emitting protrusions extending between said substrate and said current diffusion layer, a plurality of interconnected spaces disposed among and separating said light emitting protrusions from each other, and a dielectric material filling said spaces, each of said light emitting protrusions including first and second cladding layers and a light-emitting active layer sandwiched between said first and second cladding layers.

2. The light emitting device of claim 1, wherein each of said light emitting protrusions is columnar in shape.

3. The light emitting device of claim 1, wherein said substrate includes a layered structure that has a bonding layer of a metal material selected from the group consisting of Au, Al, Ti, Sn, Pt, In, Ag, Be, and gold-containing alloy.

4. The light emitting device of claim 3, wherein said bonding layer is a three-layer structure of aluminum, titanium, and gold.

5. The light emitting device of claim 3, wherein said layered structure of said substrate further has a base layer bonded to said bonding layer a and made from a metal material selected from the group consisting of Cu, copper-containing alloy, Ni, nickel-containing alloy, tungsten-molybdenum alloy, and dopant-doped silicon.

6. The light emitting device of claim 5, wherein said metal material of said base layer is copper.

7. The light emitting device of claim 5, wherein said layered structure of said substrate further has a reflective layer sandwiched between and bonded to said bonding layer and said light emitting structure, and made from a metal material selected from the group consisting of Pt, Ag, Ti, Au, Al, In, and Pd.

8. The light emitting device of claim 7, wherein said metal material of said reflective layer is Pt.

9. The light emitting device of claim 1, wherein each of said light emitting protrusions comprises a GaN type compound semiconductor material.

10. The light emitting device of claim 9, wherein said first and second cladding layers of each of said light emitting protrusions are made from n-type GaN and p-type GaN compound materials, respectively, said first cladding layers of said light emitting protrusions being bonded to said current diffusion layer, said second cladding layers of said light emitting protrusions being bonded to said substrate.

11. The light emitting device of claim 10, wherein said active layer of each of said light emitting protrusions includes a n-type AlGaN film, a p-type AlGaN film , and a multi-layer structure of InGaN/GaN sandwiched between said n-type AlGaN film and said p-type AlGaN film.

12. The light emitting device of claim 1, wherein said dielectric-material is made from silicon dioxide.

13. The light emitting device of claim 1, wherein said current diffusion layer is made from indium-tin oxide.
